(19) United States
(12) Patent Application Publication
(10) Pub. No.: US 2006/0258048 A1
(43) Pub. Date: Nov. 16, 2006

(54) INTEGRATED CAPACITOR FOR WAFER LEVEL PACKAGING APPLICATIONS

(75) Inventor: JOAN K. VRTIS, Phoenix, AZ (US)

Correspondence Address: GREENBERG TRAURIG LLP, 2450 COLORADO AVENUE, SUITE 400E, SANTA MONICA, CA, 90404, US

(73) Assignee: EKUBIK CONSULTING LLC, PHOENIX, AZ (US)

(21) Appl. No.: 11/460,232

(22) Filed: Jul. 26, 2006

Related U.S. Application Data
(62) Division of application No. 10/752,045, filed on Jan. 5, 2004.

(51) Int. Cl. H01L 21/00

(52) U.S. Cl. 438/107

(57) ABSTRACT

A capacitor design, which incorporates a material set that is adaptable to standard substrate or electronic packaging fabrication methods, uses copper as a base and electrode, mesoporous nanocomposite materials or other adhesion promoting materials combined with a high dielectric material specific to the application's capacitance requirements. This capacitor is then used as a basis for forming a capacitor in substrate or package or wafer level package or die or wafer.

### RELATED APPLICATIONS

This application is a Divisional of prior application Ser. No. 10/752,045, filed Jan. 5, 2004, entitled “System and Method for Packaging Electronic Components,” currently pending, herein incorporated by reference in its entirety.

### BACKGROUND

1. Field of the Invention

The present invention relates to packaging electronic components for providing improved power delivery, enhanced structural integrity, and reduction in the dimensions of the packaging.

2. General Background

The design goal for electronic devices, where decoupling and power dampening applications are required, is to reduce signal and power noise and/or reduce power overshoot and droop by placing a capacitor as close to the die as possible. Also, the longer the path from the die to an electronic component, such as a capacitor, the more capacitance is needed due to the increased inductance.

The current state of the art is to place the electronic components, such as capacitors, on the substrate as close to the die as possible. With respect to FIG. 1, the capacitor 10 is surface mounted with a solder 12 onto the electrical pad on the substrate 14 and is either mounted next to the die 16 (die side) or underneath the die. The die is connected to the substrate via solder 15 or wire-bonded which is standard in die connecting techniques. Thus, electronic components, such as capacitors, stand alone as discrete components and are not part of the substrate.

Hence, the prior art design provides for an inefficient power delivery mechanism, to the die, due to a fairly large physical separation between the capacitor 10 and the die 16. Furthermore, this design also degrades the structural integrity of the electronic package since the capacitor 10 is a discrete component that is soldered at a distance from the die 16. In addition, the prior art design requires (i) conventional surface mount operations for application of the discrete capacitor, (ii) high solder requirements, and (iii) large packaging dimensions (depending on the number of components and the separation of these components from the die).

### SUMMARY

Described herein is a system and method that permits integration of an electronic component (e.g., passive electronic devices such as capacitors) into a substrate package such that the component is an integral part of the substrate. This design/application substantially improves the power delivery to the die in addition to providing a rigid core for enhanced structural integrity. The integrated decoupling component/capacitor (also known as the power dampening mechanism) permits reduction of signal and power noise (viz., improvement in signal to noise ratio) and/or reduces the power overshoot and droop in electronic devices.

From a manufacturing standpoint, the system also minimizes the requirement for applying the electronic component (viz., the capacitor) through conventional surface mount operations, thereby reducing the need for solder and furthermore eliminating the need for surface mount pads on the substrate. Improvement of mechanical integrity of the device is exhibited by the minimization of the thermal mismatch between the die and substrate material which is often a source for device failure. From a design for cost aspect, the system minimizes the overall package body dimensions (viz., in the x, y, and z directions) of the substrate by incorporating the power circuits directly to the die from the integrated electronic component (such as the capacitor). The overall cost of the system and method described is substantially lower than the current conventional package+discrete-capacitor+die device.

Accordingly, in one embodiment, the described system includes an array capacitor design where the capacitor is integrated into an electronic package or substrate. In one aspect, the structure, having the capacitor, incorporates a material set that is adaptable to standard substrate or electronic packaging fabrication methods and uses (i) copper as a base and as an electrode, (ii) mesoporous nanocomposite materials or other adhesion promoting materials, and (iii) a high dielectric material specific to the application's capacitance requirements. This structure is then used as a basis for further processing to form the capacitor in substrate or package component such as a wafer level package or a silicon or other wafer material for an IC device.

Accordingly, in one embodiment, a method for providing improved power delivery to a die in an electronic package comprises: (i) forming a component (e.g., a passive electronic device) as an integral part of a substrate in the electronic package such as a wafer level package or a silicon or other material for an IC device, (ii) including the die on the substrate, wherein the integration of the component as part of the substrate permits improved power delivery to the die. In one aspect of the invention, the passive electronic device could be a capacitor. Furthermore, the substrate may be made of substantially the same material (e.g. copper) as the component. The method may further comprise the step of forming a thin film at an interface between the die and the substrate, wherein the thin film is at least one of a polyimide, polybenzoxazole, or a dielectric material used in packaging. The method may also comprise including a dielectric between a pair of electrodes of the passive electronic device to form the capacitor. In addition a cavity may be formed in the electronic component (e.g., the capacitor) to include the die.

Furthermore, in another embodiment, a method for providing a structurally robust electronic package comprises forming an electronic component (e.g., a passive device such as a capacitor) as an integral part of a substrate in the electronic package, wherein the integration of the electronic component as part of the substrate provides for a structurally robust electronic package. In one aspect, the electronic component and the substrate may be formed of substantially the same material such as copper.

In another embodiment, the integrated capacitor structure can be used in a power storage unit for the power supply used in global positioning systems or other handheld devices. This design would minimize the overall number of capacitors in handheld devices and reduce the device form factor (x, y, z dimensions of the unit).

Thus, the integrated capacitor design provides a high capacitance material set for capacitor applications and is conducive to active integration in the substrate or electronic package. In one aspect, the integrated capacitor can be designed for high capacitance greater than or equal to 1 microfarad. The integrated capacitor design provides an integrated power delivery solution for electronic devices by incorporating a planar capacitor as an integral part of the substrate or die/wafer design. This design addresses the issues of power delivery, signal and power noise, power overshoot and droop in electronic devices. The integrated capacitor design eliminates the need for discrete capacitors, close to the die, thus eliminating the requirement for a surface mounting operation and the use of solders and fluxes. The integrated capacitor design minimizes the overall body size of the substrate, by eliminating the real estate needed on the substrate for discrete capacitors, thereby providing more flexibility in design rules. The integrated capacitor design provides a higher capacitance for use as a power storage unit integrated into handheld battery powered electronic devices. Also, the integrated capacitor design provides a capacitance structure unique to fabricating the capacitor as an integral material in the electronic package and IC device construction.

### BRIEF DESCRIPTION OF THE DRAWINGS

FIG. 1 is a prior art depiction of a discrete capacitor design;

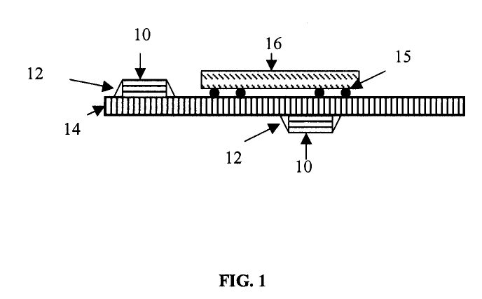

FIG. 2 is a schematic of the integrated capacitor design;

FIG. 3 is one embodiment showing the capacitor integrated with the substrate;

FIG. 4 is another embodiment showing the capacitor integrated with the substrate;

FIG. 5 is another embodiment showing the capacitor integrated with the substrate;

FIG. 6 is another embodiment showing the capacitor integrated with the substrate;

FIG. 7 is another embodiment showing the capacitor integrated with the substrate;

FIG. 8 is another embodiment showing the capacitor integrated with the substrate;

FIG. 9 is another embodiment showing the capacitor integrated with the substrate;

FIG. 10 is another embodiment showing the capacitor integrated with the substrate;

FIG. 11 is a flow chart showing the manufacturing steps for forming an integrated power delivery solution to an electronic device;

FIG. 12 depicts a flow diagram of fabricating an integrated capacitor on a copper substrate;

FIG. 13 depicts another flow diagram for fabricating an integrated capacitor on a wafer without circuitry;

FIG. 14 depicts another flow diagram for fabricating an integrated capacitor on a wafer or die with circuitry;

FIG. 15 depicts an example of a multi-layer integrated capacitance design;

FIG. 16 depicts another flow diagram for fabricating an integrated capacitor on a backside silicon or other wafer or die material;

FIG. 17 depicts another flow diagram for fabricating an integrated capacitor with topside and dual side electrode contacts;

FIG. 18 depicts another flow diagram for fabricating an integrated capacitor on a wafer scale package;

FIG. 19 represents the final build up of the capacitor on a die or wafer with existing circuitry such as a wafer level package;

FIG. 20 depicts the backside application of the capacitor on a bare silicon or other wafer/die material.

### DESCRIPTION OF THE PREFERRED EMBODIMENTS

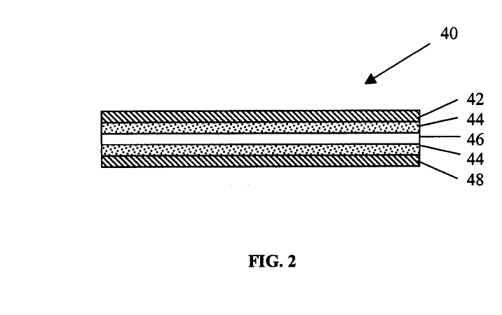

Reference will now be made in detail to exemplary embodiments which are illustrated in the accompanying drawings (FIGS. 2-20).

The integrated planar capacitor 40, as shown in FIG. 2, is formed as part of the substrate fabrication process. The capacitor 40 uses copper as the first electrode 42 which is also the rigid core base for the thin film substrate. Barium Strontium Titanate (BST), Lead Zirconate Titanate (PZT), Tantalum Oxide or other materials used in capacitor design and manufacturing and can be applied using Chemical Vapor Deposition (CVD), spin on or other coating type of techniques. A material such as mesoporous nanocomposite material 44, or other materials that promote adhesion are often applied to the copper to ensure adhesion of the high K dielectric to the copper. The mesoporous nanocomposite material 44 may be doped with a high K dielectric material 46 to further enhance the overall capacitance value. The second electrode is copper 48 which can be patterned to connect the thin film circuitry. As shown in FIG. 2, the capacitor can be fabricated with multiple repeat layers of Copper/Ad/Hi K Dielectric/Ad/Copper. The multilayer design is electrically connected in parallel (internal from layer to layer) to minimize resistance effects.

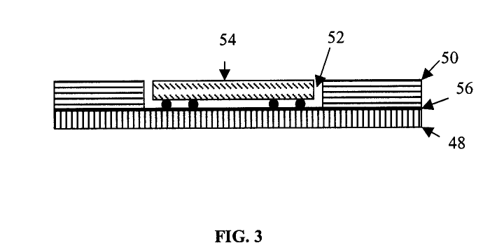

Since copper is a common material in substrate or electronic packaging, it can be patterned using standard manufacturing techniques. FIGS. 3-10 depict various substrate or electronic packaging schematics.

In FIG. 3, a portion of the capacitor structure 40 (of FIG. 2) is removed to form a cavity 52 for attaching a die 54. As can be seen, the copper layer 48 in FIG. 2 is retained as part of the substrate in FIG. 3. The thin film layer 56, which includes circuitry, interfaces the capacitor 50 and the copper substrate 48. Additionally, the thin film layer 56 is also in communication with the die 54.

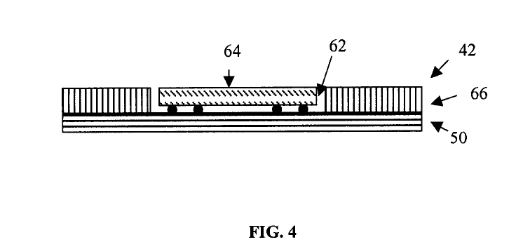

In an alternative embodiment as shown in FIG. 4, a cavity 62 is formed in the copper core 42 (of FIG. 2). A die 64 is then placed in the cavity 62 in communication with the thin film circuitry layer 66.

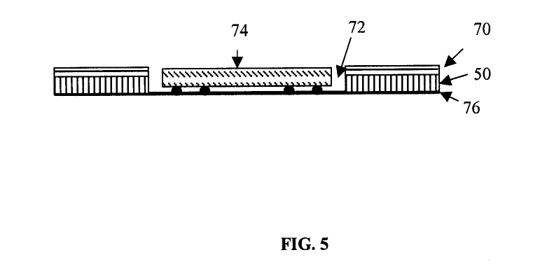

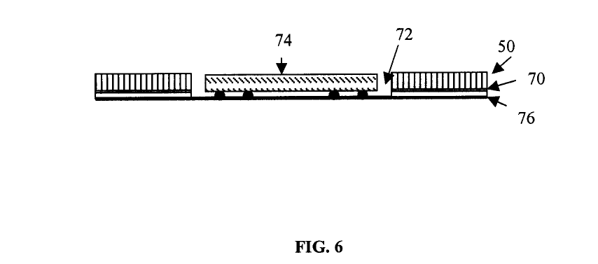

In FIGS. 5, 6, the capacitor 50 and copper core 70 are first formed as an integrated unit, and then the thin film circuitry 76 is applied. Following this, the cavity 72 is formed by removing portions of the capacitor 50 and the copper core 70. Finally, a die 74 is placed in communication with the thin film circuitry 76.

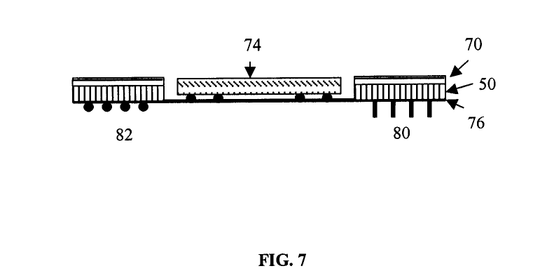

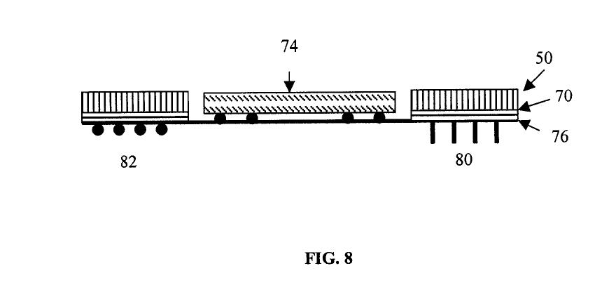

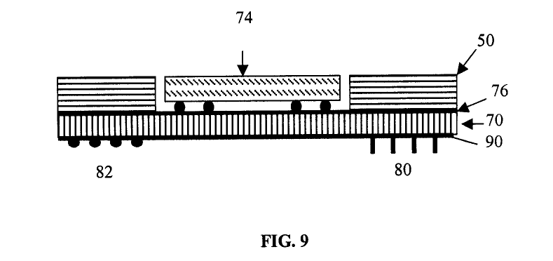

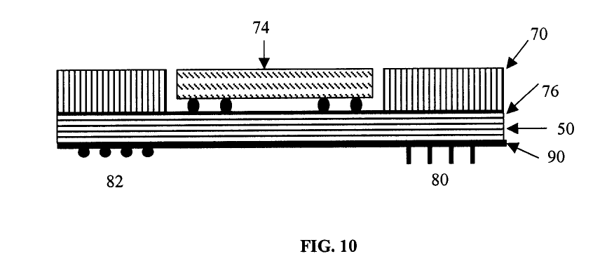

Furthermore, the capacitor 50 can be patterned to allow for interconnect solutions. For example, as shown in the embodiments of in FIGS. 7 and 8 (corresponding to FIGS. 5 and 6 respectively), solder bumps 82 or pins 80 or other interconnect technology can be attached to the thin film circuitry 76. In other variations, additional interconnect circuitry 90, which would connect the capacitor in package component to a motherboard, socket or other electronic devices, are depicted in FIGS. 9 and 10.

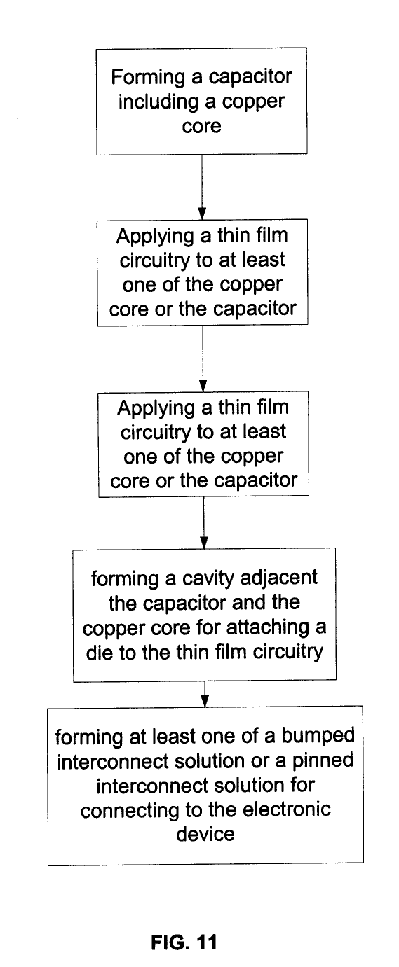

FIG. 11 is an exemplary flow chart depicting a method for providing an integrated power delivery solution to electronic devices.

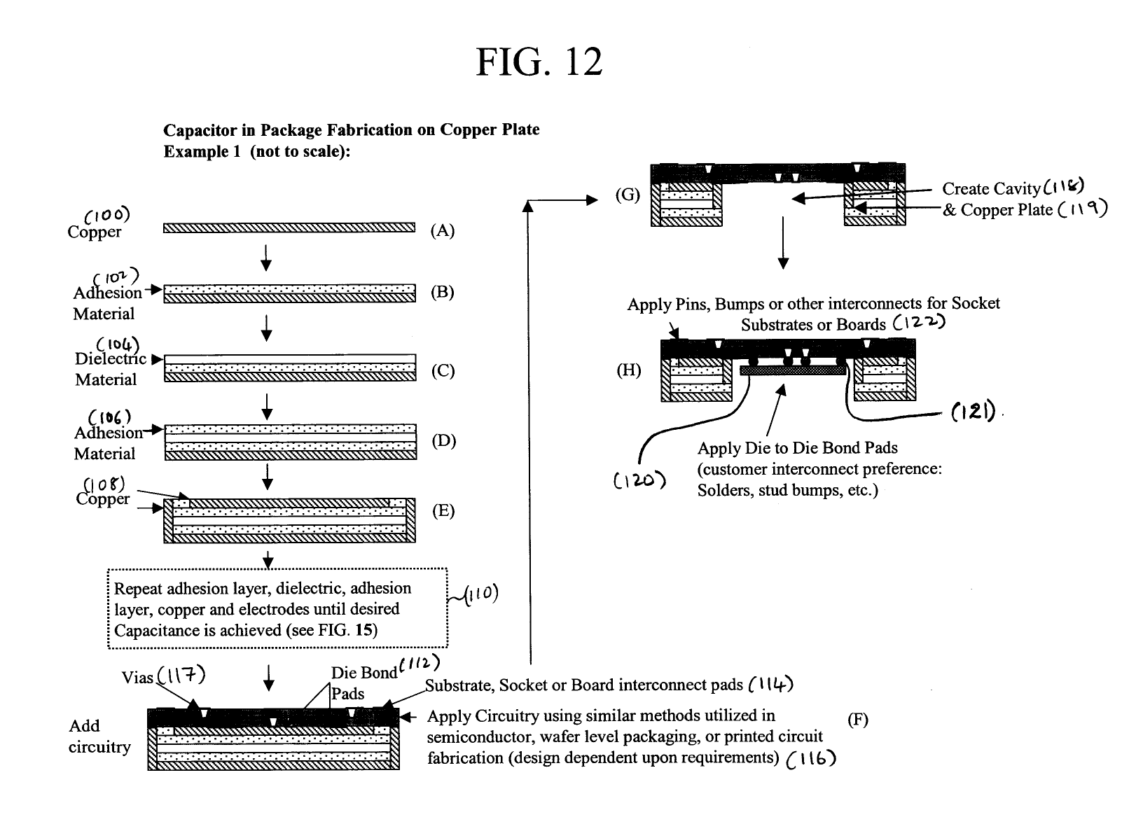

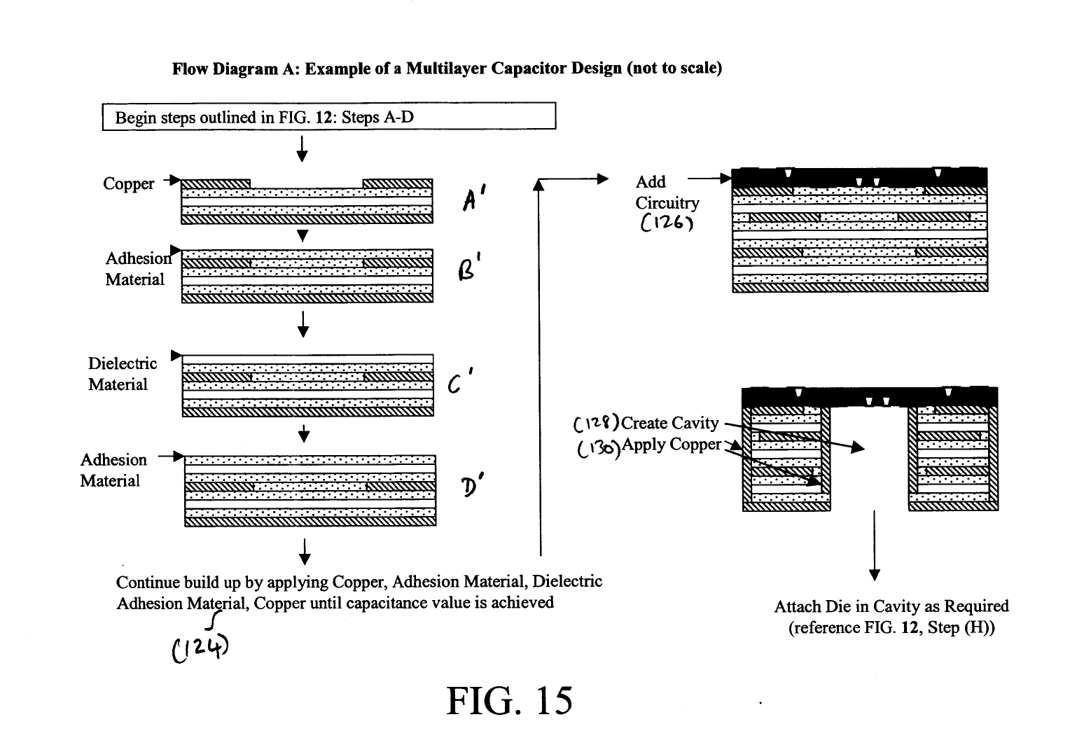

FIG. 12 depicts a flow diagram of fabricating an integrated capacitor on a copper substrate. In the first step, an adhesive material 102 is applied to the copper core 100. Subsequently, a dielectric material 104 is formed on the adhesive layer 102. At this point, another adhesive material 106 is placed on the dielectric layer 104, and finally a copper layer 108 is applied over the adhesive layer 106. As shown in step 110, the process continues until the desired capacitance is achieved. Step 110 is explained in detail later on with reference to FIG. 15. Subsequently, die bonding pads 112 are applied over the copper layer 108. Furthermore, using methods employed in semiconductor, wafer level packaging, or printed circuit fabrication, a thin film circuit layer 116 is formed over the copper layer 108. Also, the thin film circuit layer is in communication with the die bond pads 112. In the next step, substrate, socket, or board interconnect pads 114 and via connects 117 are placed in communication with the thin film circuit layer 116. In the following step, a cavity 118 and copper plate 119 are created for receiving a die 120 in contact with the die bond pads 112 using solders or stud bumps 121. Additional pins, bumps, and other interconnects 122 may be applied for socket substrates or boards.

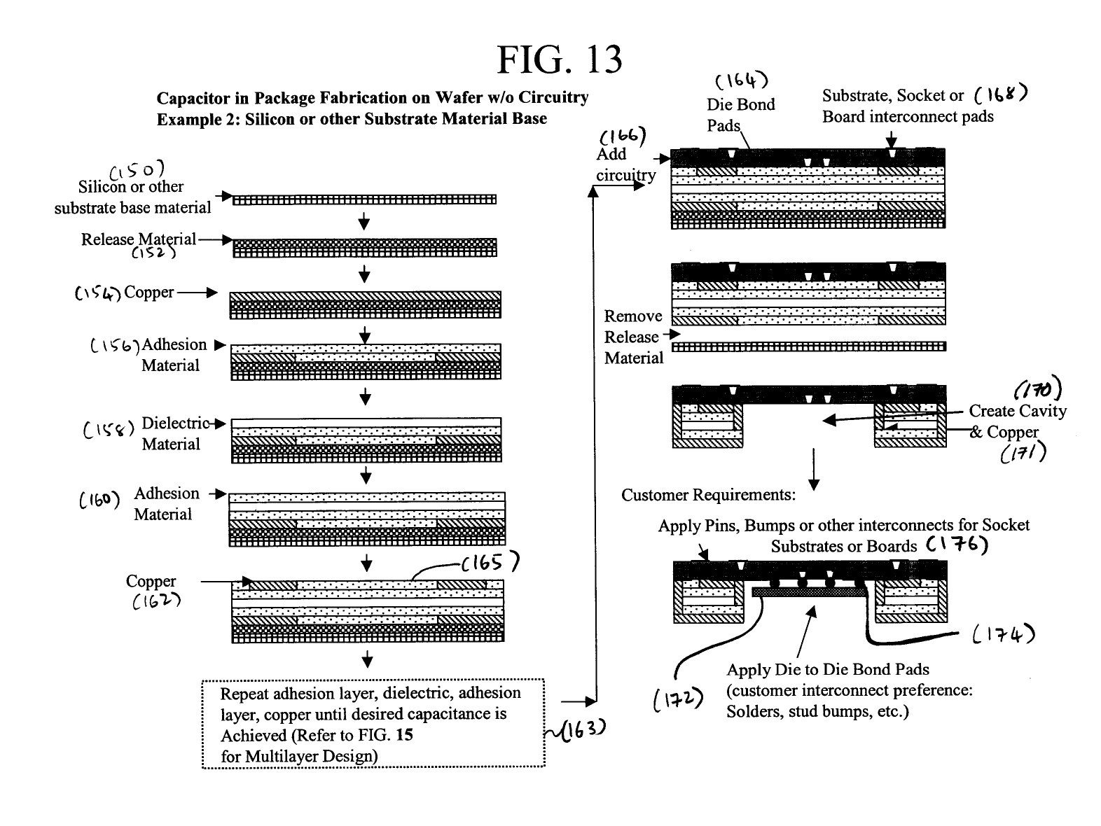

FIG. 13 depicts another flow diagram for fabricating an integrated capacitor on a wafer without circuitry. In the first step, a release material 152 is applied to the silicon or other substrate base material 150. Subsequently, copper 154 is formed on the release layer 152. At this point, an adhesive layer 156 is placed on the copper layer 154, and a dielectric material 158 is applied to the adhesive layer 156. Subsequently, another adhesive layer 160 is applied over the dielectric layer 158. Finally a copper layer 162 is applied over the adhesive layer 160. As can be seen, the copper material 162 may be combined with adhesive material 165 for depositing additional layers as shown in step 163, until the desired capacitance is achieved. Subsequently, die bonding pads 164 are applied over the copper layer 162. Furthermore, using methods employed in semiconductor, wafer level packaging, or printed circuit fabrication, a thin film circuit layer 166 is formed over the copper layer 162. Also, the thin film circuit layer is in communication with the die bond pads 164. In the next step, substrate, socket, or board interconnect pads 168 are placed in communication with the thin film circuit layer 166. In the next step, the release material 152 is removed, and a cavity 170 and copper plate 171 are created for receiving a die 172 in contact with the die bond pads 164 using solders or stud bumps 174. Additional pins, bumps, and other interconnects 176 may be applied for socket substrates or boards.

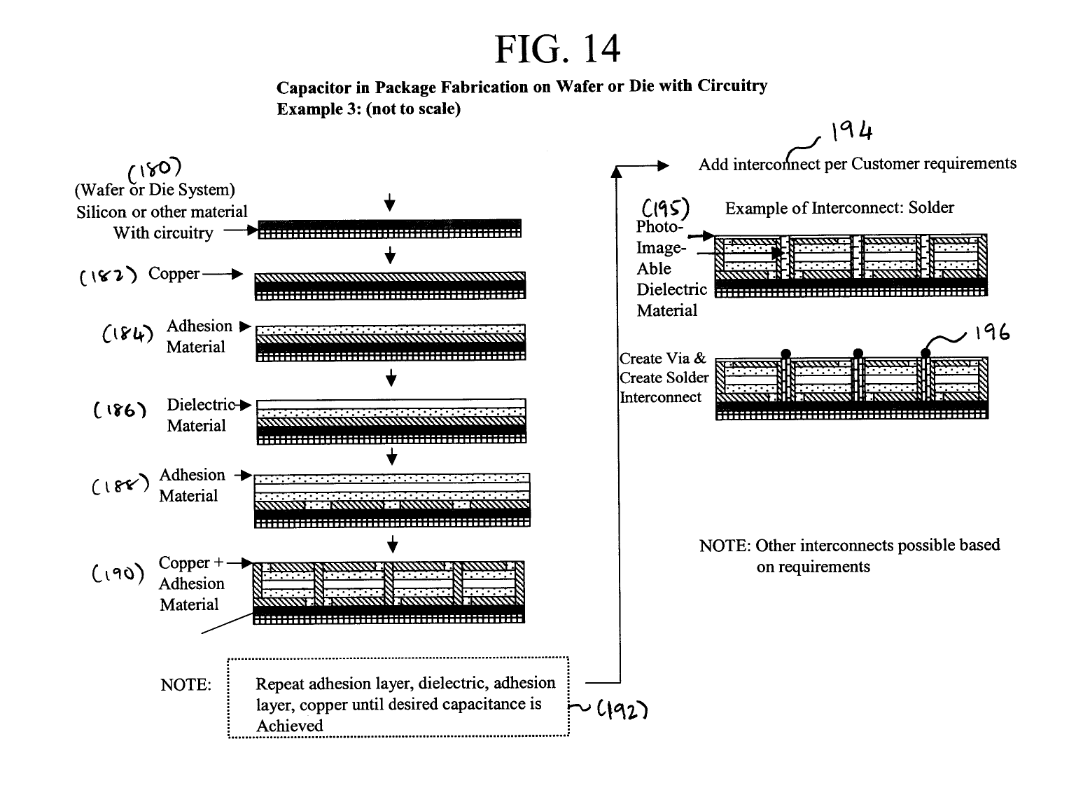

FIG. 14 depicts another flow diagram for fabricating an integrated capacitor on a wafer or die with circuitry. In the first step, a copper layer 182 is applied to the silicon (or another material) wafer or die system 180 having circuitry. At this point, an adhesive layer 184 is placed on the copper layer 182, and a dielectric material 186 is applied to the adhesive layer 184. Subsequently, another adhesive layer 188 is applied over the dielectric layer 186. Finally a copper layer 190 is applied in and around all sides of the dielectric layer and adhesive layer(s). As shown in step 192, the process continues until the desired capacitance is achieved. Subsequently, as shown in step 194, interconnects are added per customer requirements. One example is the solder interconnect shown as 196, another example is the pinned or stud bump interconnect. To form the solder interconnect, a photo-imageable dielectric material 195 is deposited over the copper layer 190, and then via and solder interconnects 196 are formed on the dielectric material.

FIG. 15 depicts an example of a multi-layer integrated capacitance design that is repeatedly fabricated, until desired capacitance is achieved, in a manner similar to Steps A-D in FIG. 12. The design is shown in Steps A′-D′ which correspond to Steps A-D in FIG. 12. After the desired capacitance value is achieved, as indicated in 124, a thin film circuitry layer 126 is added to the device, a cavity 128 is created, and finally copper 130 is applied before a die is received in the cavity 128.

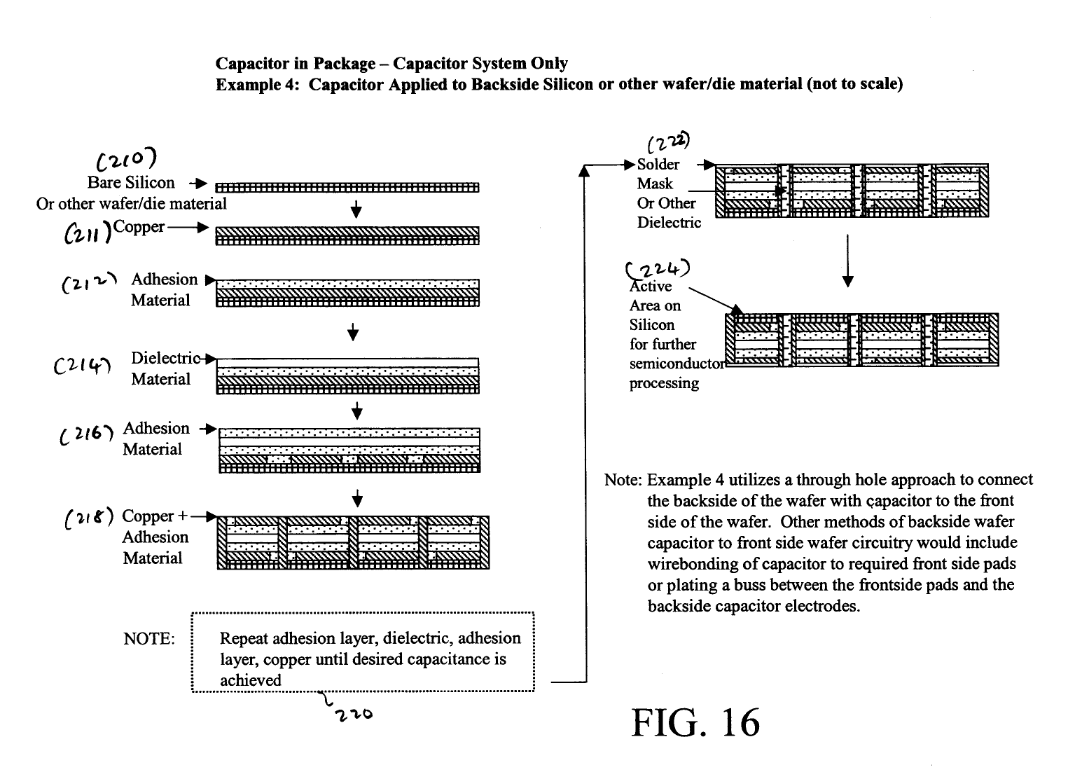

FIG. 16 depicts another flow diagram for fabricating an integrated capacitor on a backside silicon or other wafer or die material. In the first step, a copper layer 211 is deposited on a bare silicon 210 or other equivalent wafer/die material. At this point, an adhesive layer 212 is placed on the copper layer 211, and a dielectric material 214 is applied to the adhesive layer 212. Subsequently, another adhesive layer 216 is applied over the dielectric layer 214. Finally a copper layer 218 is applied in and around all sides of the dielectric layer and adhesive layer(s). As shown in step 220, the process continues until the desired capacitance is achieved. Subsequently, solder mask or other dielectric material may be applied as shown in 222. Finally, the active area on the front side (topside) of the silicon 224 is available for further semiconductor processing. It should be noted that this example uses a through-hole approach to connect the backside of the wafer, having the capacitor, to the front side of the wafer. Other methods of backside wafer capacitor to front side wafer circuitry could include wire-bonding of capacitor to required front side pads or plating a buss between the front side pads and the backside capacitor electrodes.

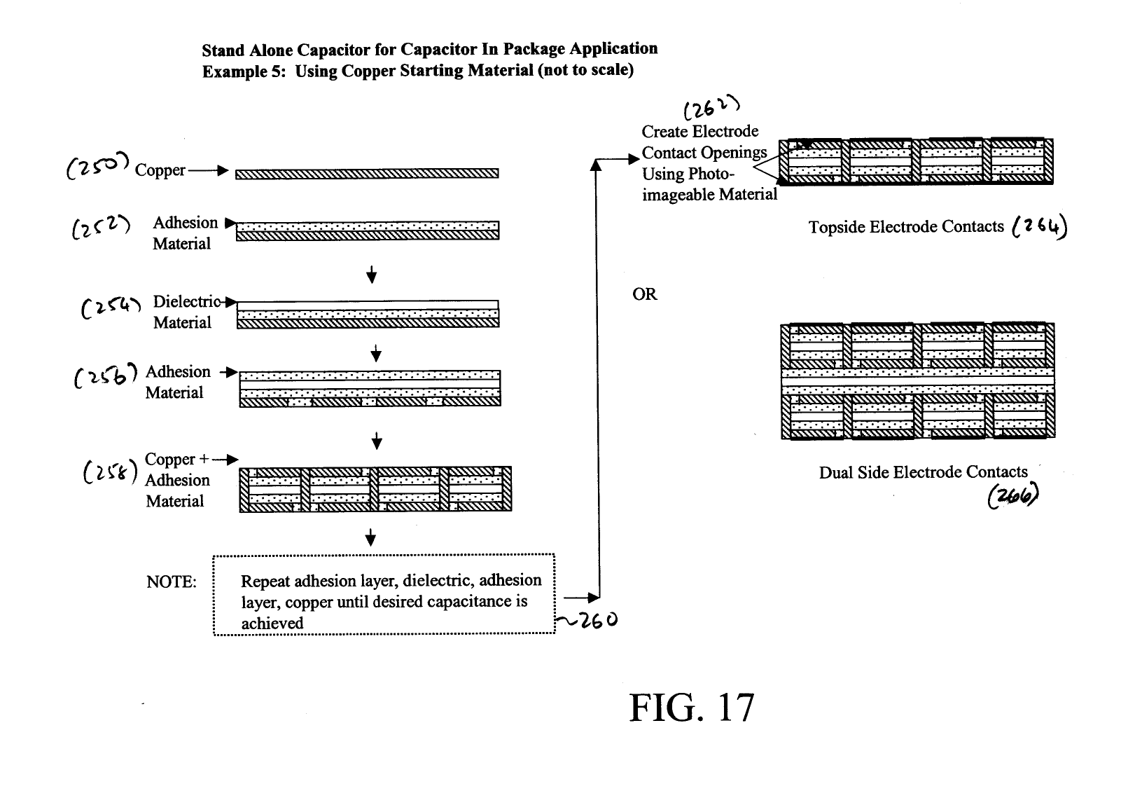

FIG. 17 depicts another flow diagram for fabricating an integrated capacitor with topside and dual side electrode contacts. In the first step, an adhesive layer 252 is placed on a copper layer 250, and a dielectric material 254 is applied to the adhesive layer 252. Subsequently, another adhesive layer 256 is applied over the dielectric layer 254. Finally, a copper layer, along with adhesive material (for subsequent material depositions until appropriate capacitance is achieved), 258 is applied in and around all sides of the dielectric layer and adhesive layer(s). As shown in step 260, the process continues until the desired capacitance is achieved. Subsequently, either electrode contact openings using photo-imageable material are created as shown in 262, or dual-side electrode contacts are created as shown in 266.

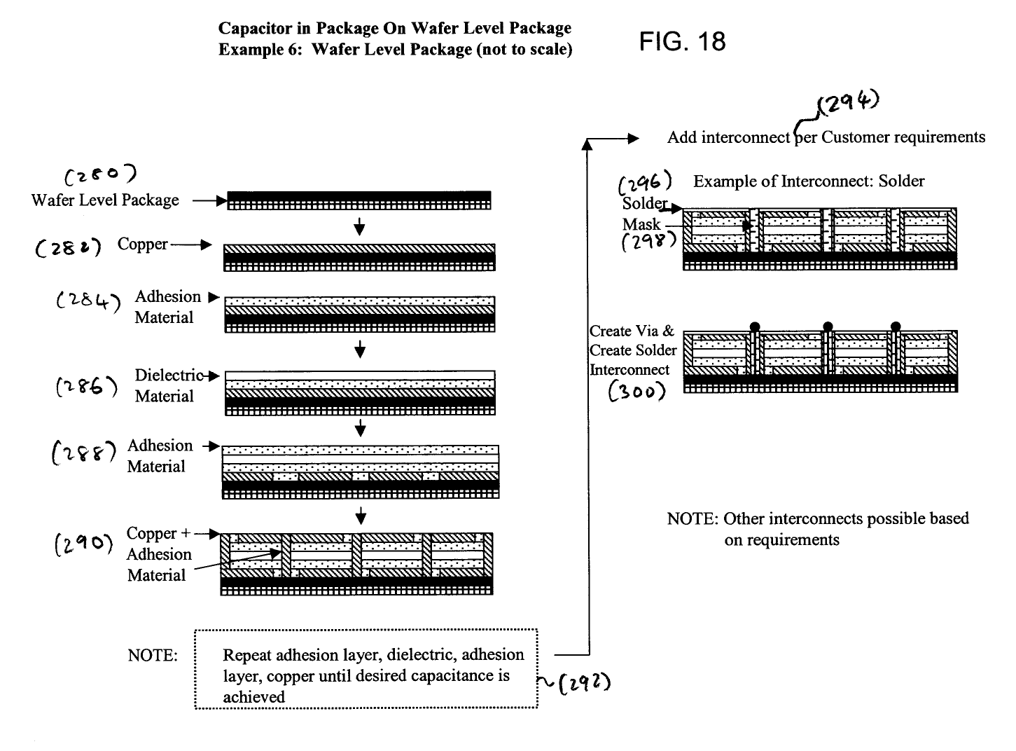

FIG. 18 depicts another flow diagram for fabricating an integrated capacitor on a wafer level package. In the first step, a copper layer 282 is deposited over a wafer level package 280. At this point, an adhesive layer 284 is placed on the copper layer 282, and a dielectric material 286 is applied to the adhesive layer 284. Subsequently, another adhesive layer 288 is applied over the dielectric layer 286. Finally a copper layer 290 is applied in and around all sides of the dielectric layer and adhesive layer(s). As shown in step 292, the process continues until the desired capacitance is achieved. Subsequently, as shown in step 294, interconnects are added per customer requirements. One example of an interconnect is the solder interconnect. In the first step for creating the solder interconnect, the solder mask material is applied to the surface of the copper and is imaged leaving an opening of exposed copper specific to interconnect design. The solder mask is also fills the interconnect vias created by laser drilling or other methods common in semiconductor processing. A subsequent via is formed using laser drilling or other methods for creating vias. The solder mask or photoimageable dielectric is used to insulate the capacitor copper from the solder thus avoiding shorting. A solder layer 296 is deposited over the copper material along with a mask 298. Subsequently, the vias and solder interconnects are formed as shown by 300.

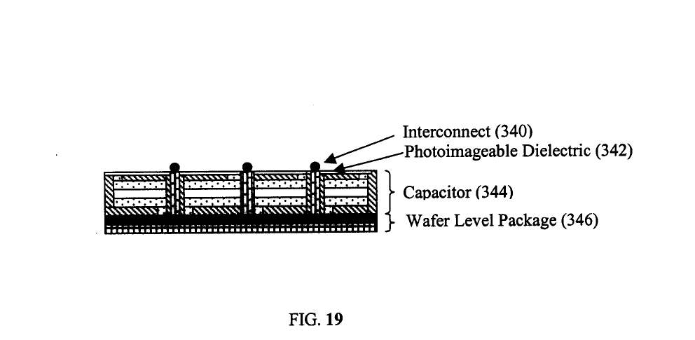

FIG. 19 represents the build up of the capacitor 344 on a die or wafer with existing circuitry such as a wafer level package 346. The wafer level package 346 is a known, common semiconductor technology. The capacitor 344 would be applied to the package such as a wafer level package 346 using the capacitor in package invention. This figure represents front side processing of the wafer with the capacitor.

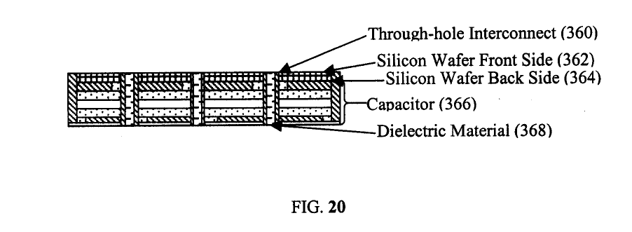

FIG. 20 depicts backside application of the capacitor on a bare silicon or other wafer/die material. In this figure, the capacitor 366 is an integral part of the semiconductor base material prior to further processing by the end user. The capacitor is built up from the back side 364 of the semiconductor base material using methods outlined in figures described earlier. The interconnect between the end user circuitry and the capacitor 366 can be achieved using through hole interconnect technology 360, wirebonding or other interconnect techniques.

As can be clearly seen, all of the above designs allow for die attachment and a reduced distance to the capacitor. Thus, the present design permits, (i) an integrated capacitor in package application, (ii) the fabrication of the capacitor as part of the substrate package design, (iii) a statistically better power delivery to the die, (iv) a statistically improved mechanical properties of the combined die, package, and capacitor device, (v) elimination of conventional surface mount operation for application of discrete capacitor, (vi) for a statistically less solder requirements.

The attached description of exemplary and anticipated embodiments of the invention have been presented for the purposes of illustration and description. They are not intended to be exhaustive or to limit the invention to the precise forms disclosed. Many modifications and variations are possible in light of the teachings herein.

We claim:

1. A method for fabricating an integrated capacitor on a copper based substrate, the method comprising:
applying a first adhesive layer to a first copper layer;
depositing a dielectric layer on the first adhesive layer;
applying a second adhesive layer over the dielectric layer;
depositing a second copper layer over the second adhesive layer;
wherein the first and second copper layers, the dielectric layer, and the first and second adhesive layers comprise a substrate with an integrated capacitor.

2. The method of claim 1 further including the step of forming a thin film circuit layer over at least one of the copper layers.

3. The method of claim 1 further including the step of forming at least one die bond pad over the copper layer.

4. The method of claim 1 further including the step of creating a cavity and a copper plate in the substrate.

5. The method of claim 4 further including the step of placing a die in the cavity in communication with the at least one die bond pad.

6. The method of claim 2 further including the step of forming interconnect pads over the thin film circuit layer.

7. A method for fabricating an integrated capacitor on a wafer or wafer level packaging, the method comprising:
applying a release layer to a base material layer;
depositing a first copper layer over the release layer;
applying a first adhesive layer to the first copper layer;
forming a dielectric layer on the first adhesive layer;
applying a second adhesive layer over the dielectric layer;
placing a second copper layer over the second adhesive layer;
wherein the first and second copper layers, the base material layer, the dielectric layer, the release layer, and the first and second adhesive layers comprise at least one of a wafer or wafer level package with an integrated capacitor.

8. The method of claim 7 further including the step of forming a thin film circuit layer over at least one of the copper layers.

9. The method of claim 7 further including the step of forming at least one die bond pad over the copper layer.

10. The method of claim 7 further including the steps of removing the release layer and creating a cavity and a copper plate in the substrate.

11. The method of claim 10 further including the step of placing a die in the cavity in communication with the at least one die bond pad.

12. The method of claim 8 further including the step of forming interconnect pads over the thin film circuit layer.

13. A method for fabricating an integrated capacitor on at least one of a wafer or die, or wafer level package, the method comprising:
applying a first copper layer over at least one of a silicon wafer or die layer, said at least one of a silicon wafer or die layer including circuitry;
depositing a first adhesive layer on the first copper layer;
forming a dielectric layer on the first adhesive layer;
applying a second adhesive layer over the dielectric layer;
placing a second copper layer over the second adhesive layer, the copper layer being applied in and around the dielectric and adhesion layers;
wherein the first and second copper layers, at least one of a silicon wafer or die layer, the dielectric layer, and the first and second adhesive layers comprise at least one of a wafer or die, or wafer level package with an integrated capacitor.

14. The method of claim 13 further including the step of forming solder interconnects proximal to the second copper layer, said solder interconnects communicating with the circuitry.

15. The method of claim 13 further including the step of forming at least one of pinned or stud bump interconnects proximal to the second copper layer, said at least one of pinned or stud bump interconnects communicating with the circuitry.

16. The method of claim 13 further including the step of creating at least one of a topside electrode contacts or a dual side electrode contacts.

17. A method for fabricating an integrated capacitor on the backside of a wafer or die, the method comprising:
applying a first copper layer over at least one of a silicon or other wafer materials or die,
depositing a first adhesive layer on the first copper layer;
forming a dielectric layer on the first adhesive layer;
applying a second adhesive layer over the dielectric layer;
placing a second copper layer over the second adhesive layer, the copper layer being applied in and around the dielectric and adhesion layers;
forming an electrical connection between the capacitor and front side of silicon or other material wafer
creating an active front side (topside) silicon wafer surface with backside capacitance
wherein the first and second copper layers, at least one of a silicon wafer or die layer, the dielectric layer, and the first and second adhesive layers comprise a wafer or die with an integrated capacitor.
